(19) United States
(12) Patent Application Publication
(10) Pub. No.: US 2017/0104154 A1
(43) Pub. Date: Apr. 13, 2017

(54) VARIABLE RESISTIVE MEMORY DEVICE HAVING A PHASE CHANGE STRUCTURE AND METHOD OF MANUFACTURING THE SAME

(71) Applicant: SK hynix Inc., Gyeonggi-do (KR)

(72) Inventors: Hyung Keun KIM, Gyeonggi-do (KR); Byoung Ki LEE, Gyeonggi-do (KR); Su Jin CHAE, Gyeonggi-do (KR)

(21) Appl. No.: 14/988,868

(22) Filed: Jan. 6, 2016

(30) Foreign Application Priority Data
Oct. 8, 2015 (KR) 10-2015-0141310

(51) Int. Cl. H01L 45/00

(52) U.S. Cl. CPC H01L 45/06; H01L 45/1616; H01L 45/1675; H01L 45/144; H01L 45/143; H01L 45/1253; H01L 45/124; H01L 45/1206

(57) ABSTRACT

A variable resistive memory device may include a phase change region, a phase change layer, a gap-filling layer and an upper electrode. The phase change region may have a sidewall and a bottom surface. The phase change layer may have a linear shape extended along the bottom surface and the sidewall of the phase change region. The gap-filling layer may be formed in a portion of the phase change region surrounded by the phase change layer. The upper electrode may be formed on the phase change layer and the gap-filling layer.

### CROSS-REFERENCES TO RELATED APPLICATION

This application claims priority under 35 U.S.C. 119(a) to Korean application No. 10-2015-0141310, filed on Oct. 8, 2015, which is herein incorporated by reference in its entirety as set forth in full.

### BACKGROUND

1. Technical Field

The inventive concept relates to a semiconductor integrated circuit device and a method of manufacturing the same, and more particularly, to a variable resistive memory device having a phase change structure and a method of manufacturing the variable resistive memory device.

2. Related Art

Recently, a variable resistive memory device, which is one of next generation memory devices and uses a variable resistive material such as a memory medium, is being widely developed. Typically, the variable resistive memory device may include a phase change memory device, a resistive memory device, a magnetic resistive memory device, etc.

The variable resistive memory device, particularly the phase change memory device, may include an access device and a phase change layer. The phase change memory device may store “0” or “1” in accordance with crystalline states of the phase change layer. The crystalline states of the phase change layer may be changed by a current, such as, a reset current applied to the phase change layer.

The phase change memory device may require effective changes of the crystalline states in the phase change layer using a small amount of the reset current. In order to reduce the reset current, the phase change layer needs to be reduced in size.

However, when a phase change region has a small size, it may be difficult to form the phase change layer in a phase change region. Thus, a disconnection may occur between the phase change layer and an upper electrode or a lower electrode.

### SUMMARY

According to an embodiment, there is provided a variable resistive memory device. The variable resistive memory device may include a phase change region, a phase change layer, a gap-filling layer and an upper electrode. The phase change region may have a sidewall and a bottom surface. The phase change layer may have a linear shape extended along the bottom surface and the sidewall of the phase change region. The gap-filling layer may be formed in a portion of the phase change region surrounded by the phase change layer. The upper electrode may be formed on the phase change layer and the gap-filling layer.

According to an embodiment, there is provided a variable resistive memory device. The variable resistive memory device may include a semiconductor substrate, a lower electrode, an insulating interlayer, a phase change layer, a gap-filling layer and an upper electrode. The semiconductor substrate may include an access device. The lower electrode may be formed on the access device. The insulating interlayer may be formed on the semiconductor substrate with the access device and the lower electrode. The insulating interlayer may have a phase change contact hole configured to expose the lower electrode. The phase change layer may be extended along a bottom surface and a sidewall of the phase change contact hole. The gap-filling layer may be formed in a portion of the phase change contact hole above the phase change layer. The upper electrode may be formed on the phase change layer and the gap-filling layer.

According to an embodiment, there is provided a method of manufacturing a variable resistive memory device. In the method of manufacturing the variable resistive memory device, an insulating interlayer having a phase change contact hole may be formed on a semiconductor substrate. A preliminary phase change layer may be formed on a surface of the insulating interlayer and an inner surface of the phase change contact hole. A preliminary gap-filling layer may be formed on the preliminary phase change layer to fill up the phase change contact hole. The preliminary gap-filling layer may be partially removed to form a gap-filling layer in the phase change contact hole. The preliminary phase change layer may be etched to form a phase change layer in the phase change contact hole. The phase change contact hole may be filled with an upper electrode.

### BRIEF DESCRIPTION OF THE DRAWINGS

FIGS. 1 to 5 are cross-sectional views illustrating a method of manufacturing a variable resistive memory device in accordance with example embodiments.

FIG. 6 is a perspective view illustrating a variable resistive memory device in accordance with example embodiments.

FIGS. 7 to 11 are cross-sectional views illustrating a method of manufacturing a three-dimensional variable resistive memory device in accordance with example embodiments.

FIG. 12 is a schematic diagram illustrating a memory card according to an embodiment of the inventive concept.

FIG. 13 is a block diagram illustrating an electronic system according to an embodiment of the inventive concept.

FIG. 14 is a block diagram illustrating a data storage apparatus according to an embodiment of the inventive concept.

FIG. 15 is a block diagram illustrating an electronic apparatus according to an embodiment of the inventive concept.

### DETAILED DESCRIPTION

Hereinafter, various embodiments will be described in greater detail with reference to the accompanying figures. Various embodiments are described with reference to cross-sectional Illustrations that are schematic illustrations of embodiments and intermediate structures. As such, variations from the shapes of the illustrations as a result, for example, of manufacturing techniques and/or tolerances, are to be expected. Thus, various embodiments should not be construed as limited to the particular shapes of regions illustrated herein but may include deviations in shapes that result, for example, from manufacturing. In the figures, lengths and sizes of layers and regions may be exaggerated for clarity. Like reference numerals in the figures denote like elements. It is also understood that when a layer is referred to as being “on” another layer or substrate, it can be directly on the other or substrate, or intervening layers may also be present.

The inventive concept is described with reference to cross-section and/or plan illustrations that are schematic illustrations of idealized embodiments of the inventive concept. However, embodiments of the inventive concept should not be construed as limited to the inventive concept. Although a few embodiments of the inventive concept will be shown and described, it will be appreciated by those of ordinary skill in the art that changes may be made in these embodiments without departing from the principles and spirit of the inventive concept.

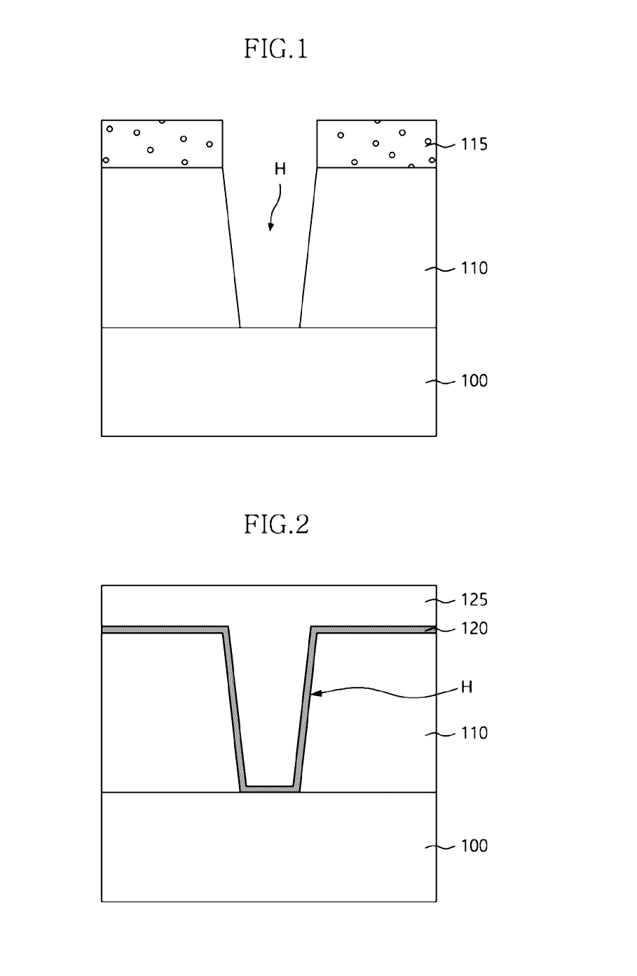

FIGS. 1 to 5 are cross-sectional views illustrating a method of manufacturing a variable resistive memory device in accordance with example embodiments.

Referring to FIG. 1, a semiconductor substrate 100 may be prepared. Although not depicted in drawings, the semiconductor substrate 100 may include an access device and a lower electrode. An insulating interlayer 110 may be formed on an upper surface of the semiconductor substrate 100. The insulating interlayer 110 may include a single insulating layer or a multi-insulating layer. A mask pattern 115 may be formed on an upper surface of the insulating interlayer 110. The mask pattern 115 may be configured to define a phase change region. The mask pattern 115 may include a material having an etching selectivity with respect to the insulating interlayer 110. For example, the mask pattern 115 may include a polysilicon layer, a photoresist pattern, etc. The insulating interlayer 110 may be etched using the mask pattern 115 as an etch mask to form a phase change contact hole H. The phase change contact hole H may have a diameter considered a reset current. As known well, as the diameter of the phase change contact hole H increases, the reset current decreases.

Referring to FIG. 2, the mask pattern 15 may be removed. A preliminary phase change layer 120 may be formed on the upper surface of the insulating interlayer 110 and an inner surface of the phase change contact hole H. The preliminary phase change layer 120 may include a material for storing data in accordance with crystalline states such as chalcogenide. For example, the preliminary phase change layer 120 may include Ge—Te, Ge—Sb—Te, Ge—Te—Se, Ge—Te—As, Ge—Te—Sn, Ge—Te—Ti, Ge—Bi—Te, Ge—Sn—Sb—Te, Ge—Sb—Se—Te, Ge—Sb—Te—S, Ge—Te—Sn—O, Ge—Te—Sn—Au, Ge—Te—Sn—Pd, Sb—Te, Se—Te—Sn, Sb—Se—Bi, In—Se, In—Sb—Te, Sb—Se, Ag—In—Sb—Te, or a combination thereof.

In example embodiments, the preliminary phase change layer 120 may include a chalcogenide alloy such as Ge—Sb—Te, As—Sb—Te, Sn—Sb—Te, Sn—In—Sb—Te, As—Ge—Sb—Te, etc. Alternatively, the preliminary phase change layer 120 may include (VA group element)-Sb—Te such as Ta—Sb—Te, Nb—Sb—Te, V—Sb—Te, etc., or (VA group element)-Sb—Se such as Ta—Sb—Se, Nb—Sb—Se, V—Sb—Se, etc. Further, the preliminary phase change layer 120 may include (VIA group element)-Sb—Te such as W—Sb—Te, Mo—Sb—Te, Cr—Sb—Te, etc., or (VIA group element)-Sb—Se such as W—Sb—Se—, Mo—Sb—Se, Cr—Sb—Se, etc.

In example embodiments, the preliminary phase change layer 120 may include the ternary chalcogenide alloy. Alternatively, the phase change layer 120 may include a binary chalcogenide alloy, a quaternary chalcogenide alloy. For example, the binary chalcogenide alloy may include Ga—Sb, In—Sb, In—Se, Sb—Te, etc. The quaternary chalcogenide alloy may include Ag—In—Sb—Te, (Ge—Sn)—Sb—Te, Ge—Sb—(Se—Te), Te—Ge—Sb—S.

In order to form the preliminary phase change layer 120 having uniform thickness in a narrow space or in a small area, the preliminary phase change layer 120 may be formed by an atomic layer deposition (ALD) process. A phase change material may be deposited by the ALD process to form the preliminary phase change layer 120 having the uniform thickness in the narrow space without a rupture. Further, the preliminary phase change layer 120 may have a linear shape and extend along the bottom surface and the sidewall of the phase change contact hole H. Therefore, it may not be required to fill up the phase change contact hole H with the preliminary phase change layer 120 so that the variable resistive memory device may be formed in a short time period, and voids and seams may be suppressed.

A preliminary gap-filling layer 125 may be formed on an upper surface of the preliminary phase change layer 120 to fill up the phase change contact hole H. The preliminary gap-filling layer 125 may include a spin coating insulating layer.

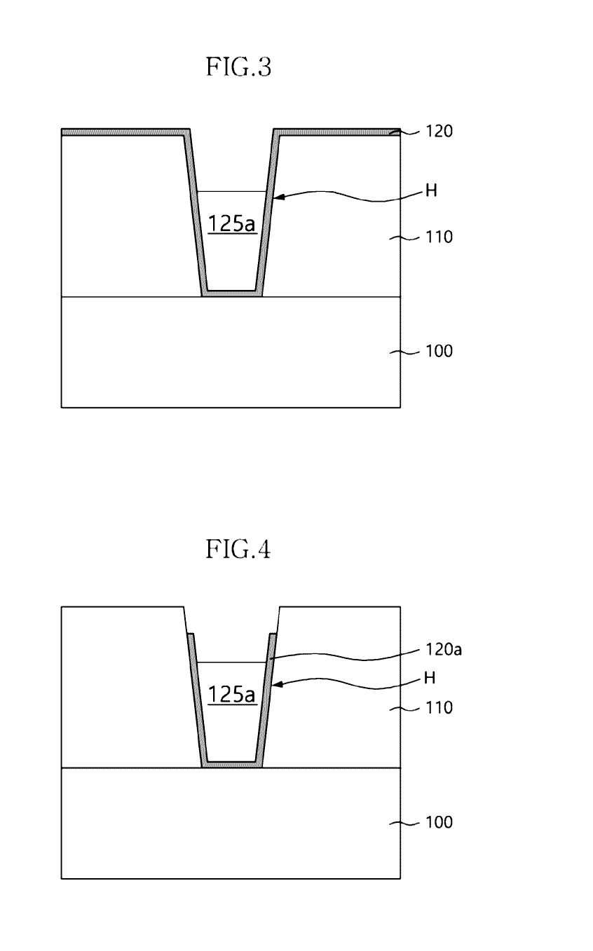

Referring to FIG. 3, the preliminary gap-filling layer 125 may be partially removed to form a gap-filling layer 125a in the phase change contact hole H. The gap-filling layer 125a may have a thickness less than a depth of the phase change contact hole H.

Referring to FIG. 4, the preliminary phase change layer 120 may be etched to form a phase change layer 120a in the phase change contact hole H. The preliminary phase change layer 120 may be anisotropically etched to expose an upper portion of the sidewall of the phase change contact hole H. An upper surface of the phase change layer 120a may be located at a higher level than an upper surface of the gap-filling layer 125a. Thus, a stepped portion may be formed between the phase change layer 120a and the gap-filling layer 125a.

A lower region of the phase change contact hole H may be filled with the linear phase change layer 120a and the gap-filling layer 125a. In contrast, an upper region of the phase change contact hole H may be an empty space.

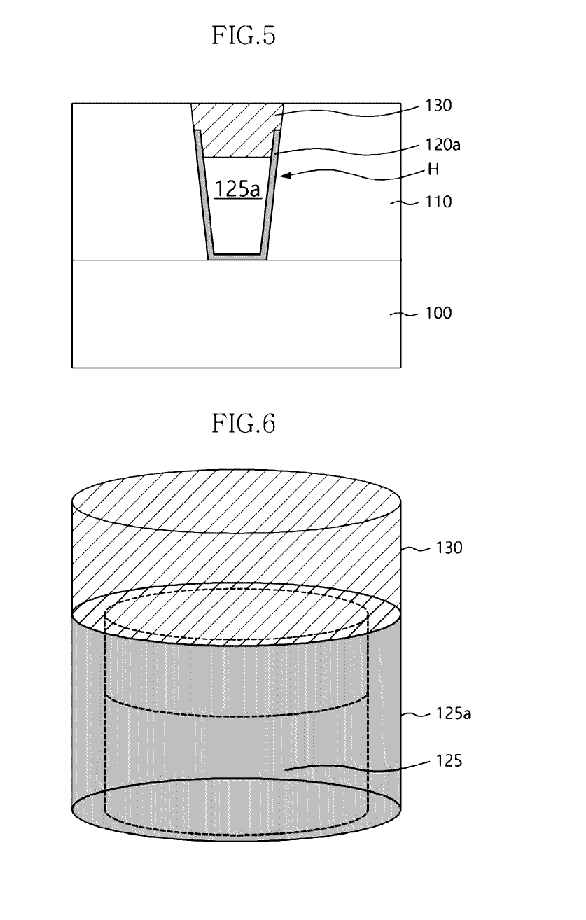

Referring to FIG. 5, the upper region of the phase change contact hole H may be filled with an upper electrode 130. The upper electrode 130 may include W, Cu, TiN, TaN, WN, MoN, NbN, TiSiN, TiAlN, TiBN, ZrSiN, WSiN, WBN, ZrAlN, MoSiN, MoAlN, TaSiN, TaAlN, Ti, Mo, Ta, TiSi, TaSi, TiW, TiON, TiAlON, WON, TaON, a doped polysilicon layer, or a combination thereof.

FIG. 6 is a perspective view illustrating a variable resistive memory device in accordance with example embodiments. Referring to FIG. 6, the linear phase change layer 120a may be formed on the sidewall and the bottom surface of the cylindrical phase change region, that is, the phase change contact hole H. The gap-filling layer 125a may be formed in the lower region of the phase change region surrounded by the phase change layer 120a. The upper electrode 130 may be formed on the phase change layer 120a and the gap-filling layer 125a. The phase change layer 120a may be configured to make a contact with the upper electrode 130. Therefore, a contact area between the phase change layer 120a and the upper electrode 130 may be remarkably reduced so that a reset current may be decreased.

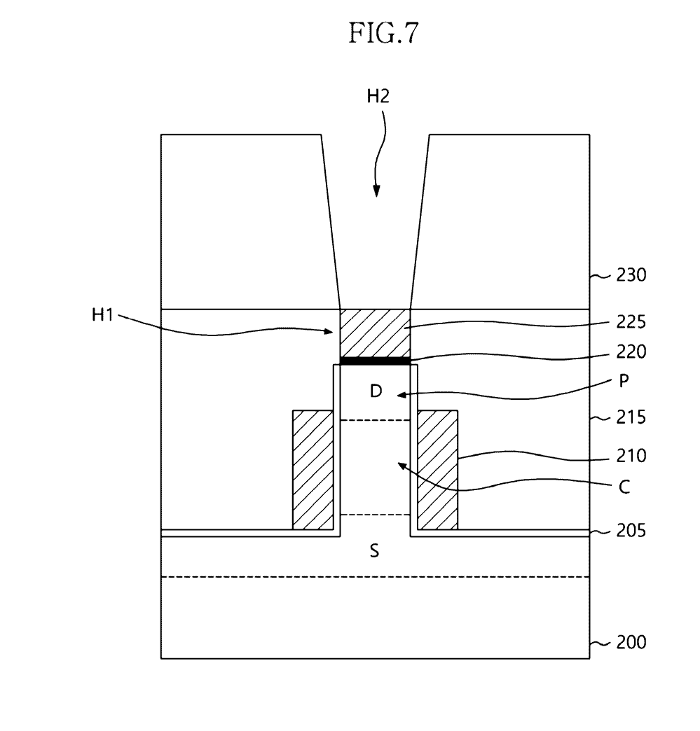

FIGS. 7 to 11 are cross-sectional views Illustrating a method of manufacturing a three-dimensional variable resistive memory device In accordance with example embodiments. Referring to FIG. 7, a semiconductor substrate 200 may be etched to form a vertical pillar P. Before forming the vertical pillar P, a common source S may be formed in the semiconductor substrate 200. Alternatively, after forming the vertical pillar P, impurities may be implanted into the semiconductor substrate 200 and a lower region of the vertical pillar P to form the common source S. Impurities may be implanted into an upper region of the vertical pillar P to form a drain region D.

A gate Insulating layer 205 may be formed on a sidewall of the vertical pillar P. A conductive layer may be formed on an upper surface of the gate insulating layer 205. The conductive layer may be anisotropically etched to form a surround gate 210 which is configured to surround the vertical pillar P, thereby forming a three-dimensional (3D) access device. Thus, the three-dimensional (3D) access device may include a channel C substantially perpendicular to the upper surface of the semiconductor substrate 200. The channel is generated between the source and drain of the vertical pillar P. Alternatively, the common source S and the drain region D may be formed after forming the surround gate 210.

A space between the 3D access devices may be filled with a first insulating interlayer 215. The first insulating interlayer 215 may be etched until the drain D may be exposed to form a contact hole H1. An ohmic contact layer 220 may be formed on the drain D which is exposed through the contact hole H1. A lower electrode 225 may be formed on the ohmic contact layer 220 to fill up the contact hole H1. The lower electrode 225 may include W, Cu, TiN, TaN, WN, MoN, NbN, TiSiN, TiAlN, TiBN, ZrSiN, WSiN, WBN, ZrAlN, MoSiN, MoAlN, TaSiN, TaAlN, Ti, Mo, Ta, TiSi, TaSi, TiW, TiON, TiAlON, WON, TaON, a doped polysilicon layer, or a combination thereof.

A second insulating interlayer 230 may be formed on the lower electrode 225 and the first insulating interlayer 215. The second insulating interlayer 230 may be etched until the lower electrode 225 may be exposed to form a phase change contact hole H2.

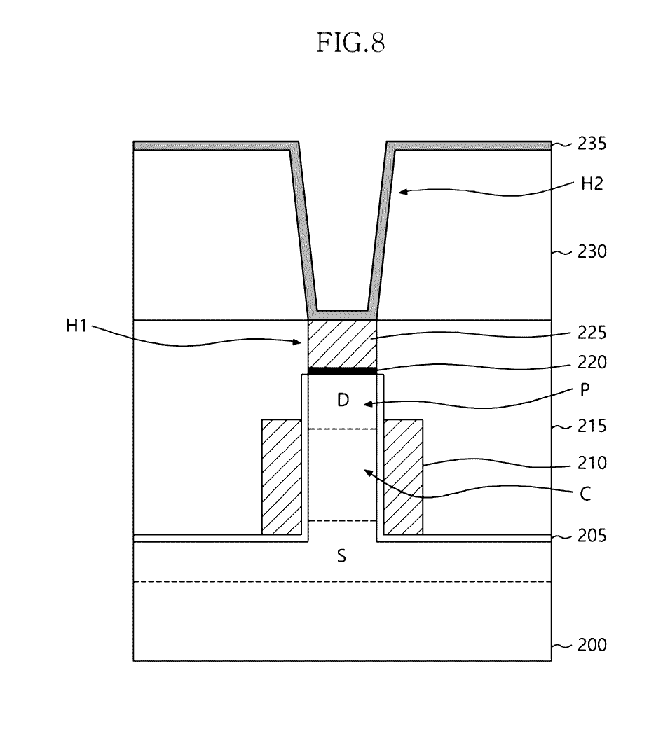

Referring to FIG. 8, a preliminary phase change layer 235 may be formed on an upper surface of the second insulating interlayer 110 and an inner surface of the phase change contact hole H2. The preliminary phase change layer 235 has a uniform thickness. The preliminary phase change layer 235 may be formed by an atomic layer deposition (ALD) process. The preliminary phase change layer 235 may include chalcogenide. For example, the preliminary phase change layer 235 may include Ge—Te, Ge—Sb—Te, Ge—Te—Se, Ge—Te—As, Ge—Te—Sn, Ge—Te—Ti, Ge—BI—Te, Ge—Sn—Sb—Te, Ge—Sb—Se—Te, Ge—Sb—Te—S, Ge—Te—Sn—O, Ge—Te—Sn—Au, Ge—Te—Sn—Pd, Sb—Te, Se—Te—Sn, Sb—Se—Bi, In—Se, In—Sb—Te, Sb—Se, Ag—In—Sb—Te, or a combination thereof.

In example embodiments, the preliminary phase change layer 235 may include a chalcogenide alloy such as Ge—Sb—Te, As—Sb—Te, Sn—Sb—Te, Sn—In—Sb—Te, As—Ge—Sb—Te, etc. Alternatively, the preliminary phase change layer 235 may include (VA group element)-Sb—Te such as Ta—Sb—Te, Nb—Sb—Te, V—Sb—Te, etc., or (VA group element)-Sb—Se such as Ta—Sb—Se, Nb—Sb—Se, V—Sb—Se, etc. Further, the preliminary phase change layer 235 may include (VIA group element)-Sb—Te such as W—Sb—Te, Mo—Sb—Te, Cr—Sb—Te, etc. or (VIA group element)-Sb—Se such as W—Sb—Se, Mo—Sb—Se, Cr—Sb—Se, etc.

In example embodiments, the preliminary phase change layer 235 may include the ternary chalcogenide alloy as mentioned above. Alternatively, the phase change layer 235 may include a binary chalcogenide alloy, a quaternary chalcogenide alloy. For example, the binary chalcogenide alloy may include Ga—Sb, In—Sb, In—Se, Sb—Te, etc. The quaternary chalcogenide alloy may include Ag—In—Sb—Te, (Ge—Sn)—Sb—Te, Ge—Sb—(Se—Te), Te—Ge—Sb—S, etc.

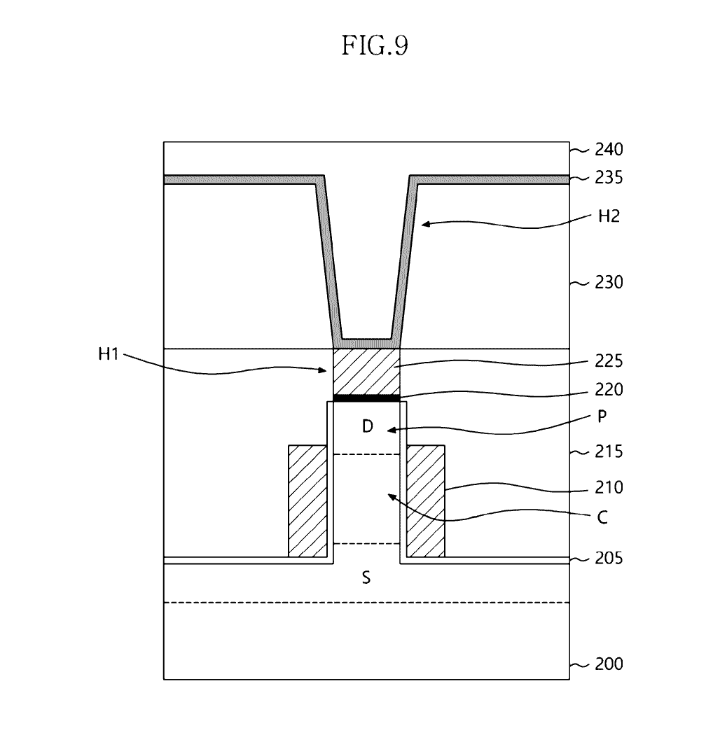

Referring to FIG. 9, a preliminary gap-filling layer 240 may be formed on an upper surface of the preliminary phase change layer 235 to fill up the phase change contact hole H2. The preliminary gap-filling layer 240 may include an Insulating layer, for example, a spin coating insulating layer.

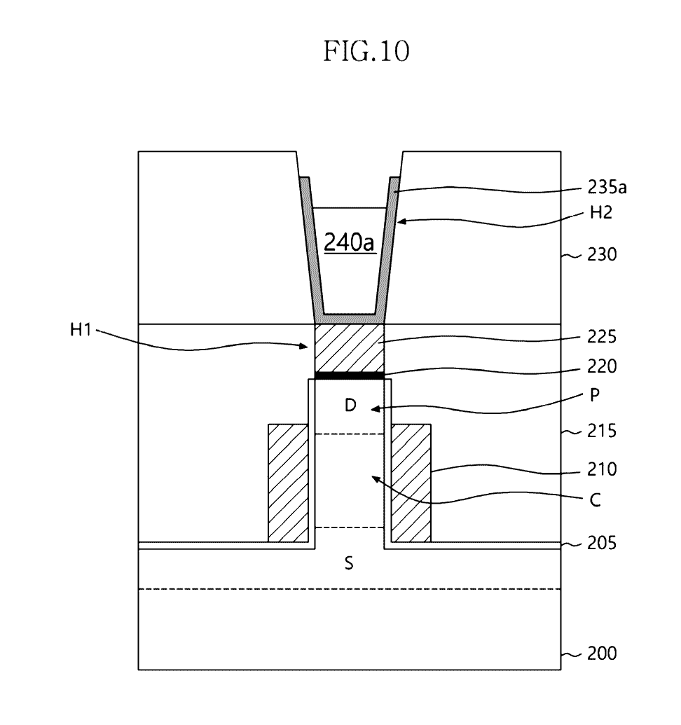

Referring to FIG. 10, the preliminary gap-filling layer 240 may be partially removed to form a gap-filling layer 240a in the phase change contact hole H2. The gap-filling layer 240a may have a thickness less than a depth of the phase change contact hole H2.

The preliminary phase change layer 235 may be etched to form a phase change layer 235a in the phase change contact hole H2. The preliminary phase change layer 235 may be anisotropically etched to expose an upper portion of the sidewall of the phase change contact hole H2. An upper surface of the phase change layer 235a may be located at a higher level than an upper surface of the gap-filling layer 240a. Thus, a step may be formed between the phase change layer 235a and the gap-filling layer 240a.

As such, a lower region of the phase change contact hole H2 may be filled with the linear phase change layer 235a and the gap-filling layer 240a. In contrast, an upper region of the phase change contact hole H2 may be left as an empty space.

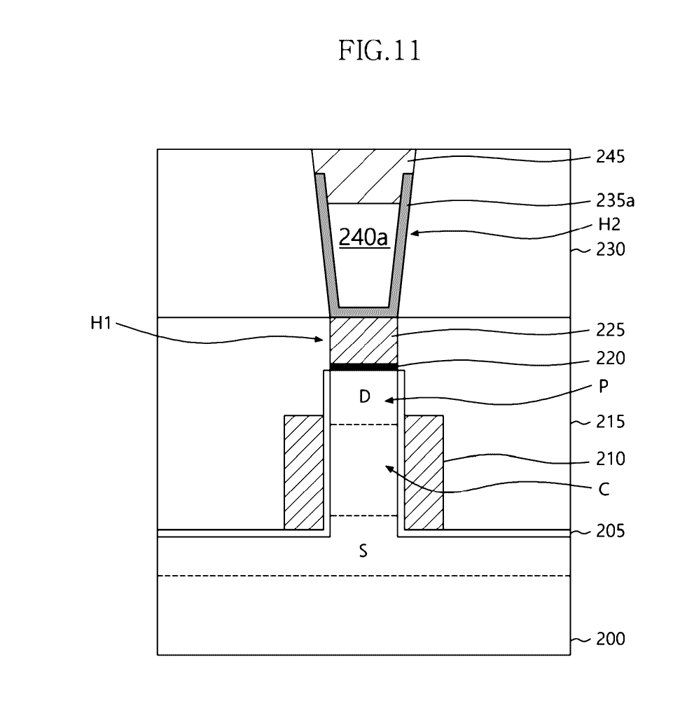

Referring to FIG. 11, the upper region of the phase change contact hole H2 may be filled with an upper electrode 245. The upper electrode 245 may include W, Cu, TiN, TaN, WN, MoN, NbN, TiSiN, TiAlN, TiBN, ZrSiN, WSiN, WBN, ZrAlN, MoSiN, MoAlN, TaSiN, TaAlN, Ti, Mo, Ta, TiSi, TaSi, TiW, TiON, TiAlON, WON, TaON, a doped polysilicon layer, etc. Since the step is formed on the upper region of the phase change contact hole H2, the upper region of the phase change contact hole H2 may be readily filled with the upper electrode 245.

According to example embodiments, the phase change layer may be formed along the sidewall of the phase change contact hole having a high aspect ratio. The gap-filling layer may be formed in the space surrounded by the phase change layer. Since the phase change layer may be formed by the ALD process, the phase change layer may be readily formed on the sidewall of the phase change contact hole without a rupture. Thus, a void or a rupture may be suppressed when the gap-filling layer is formed.

Further, the phase change layer may have the liner shape and the gap-filling layer may be formed in the space surrounded by the phase change layer. Therefore, the contact area between the upper electrode 245 and the phase change layer 235a may be relatively small so that the phase change memory device may have improved electrical characteristics.

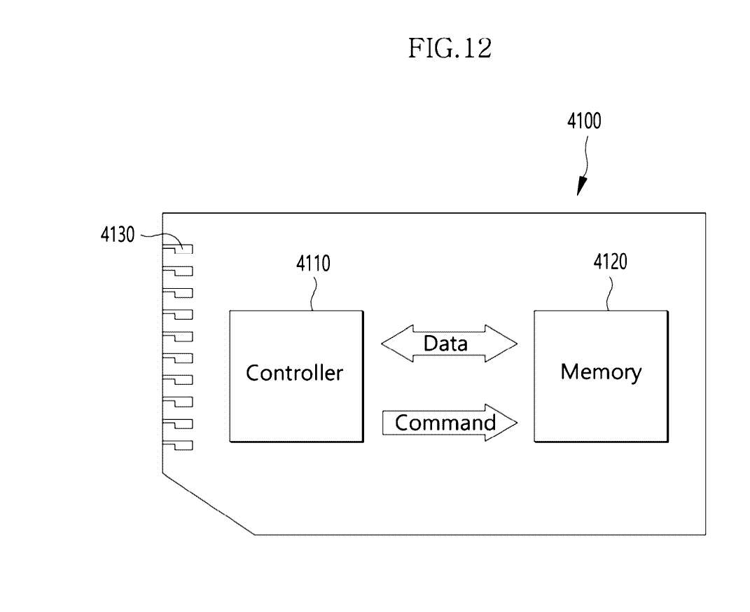

FIG. 12 is a schematic diagram Illustrating a memory card according to an embodiment of the inventive concept. Referring to FIG. 12, a memory card system 4100 including a controller 4110, a memory 4120, and an interface member 4130 may be provided. The controller 4110 and the memory 4120 may be configured to exchange a command and/or data. For example, the memory 4120 may be used to store a command to be executed by the controller 4110 and/or user data.

The memory card system 4100 may store data in the memory 4120 or output data from the memory 4120 to the outside. The memory 4120 may include the semiconductor integrated circuit device according to any one of the above-described embodiments. The controller 4110 may transmit a test command to a probe test pad in an embodiment of the inventive concept. Further, a non-contact test between the probe test pad and a probe card may be performed.

The interface member 4130 may function to input and output data from and to the outside. The memory card system 4100 may be a multimedia card (MMC), a secure digital card (SD) or a portable data storage device.

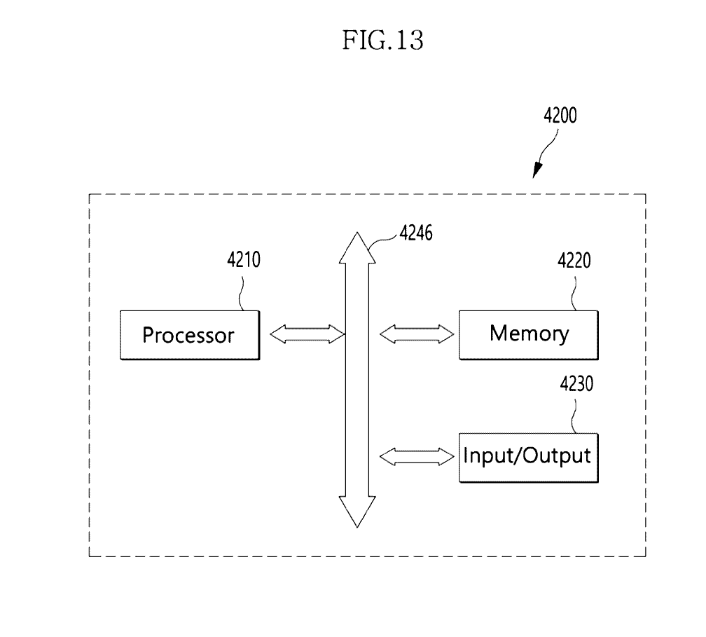

FIG. 13 is a block diagram Illustrating an electronic system according to an embodiment of the inventive concept. Referring to FIG. 13, an electronic apparatus 4200 including a processor 4210, a memory 4220, and an input/output (I/O) device 4230 may be provided. The processor 4210, the memory 4220, and the I/O device 4230 may be electrically coupled through a bus 4246.

The memory 4220 may receive a control signal from the processor 4210. The memory 4220 may store a code and data for the operation of the processor 4210. The memory 4220 may be used to store data which is accessed through the bus 4246.

The memory 4220 may include the semiconductor integrated circuit device according to any one of the above-described embodiments. In order for detailed realization and modification, additional circuits and control signals may be provided.

The electronic apparatus 4200 may constitute various electronic control apparatuses which need the memory 4220. For example, the electronic apparatus 4200 may be used in a computer system or a wireless communication device, such as a personal digital assistant (PDA), a laptop computer, a portable computer, a web tablet, a wireless phone, a portable phone, a digital music player, an MP3 player, a navigator, a solid state disk (SSD), a household appliance, or any device capable of transmitting and receiving information under wireless circumstances.

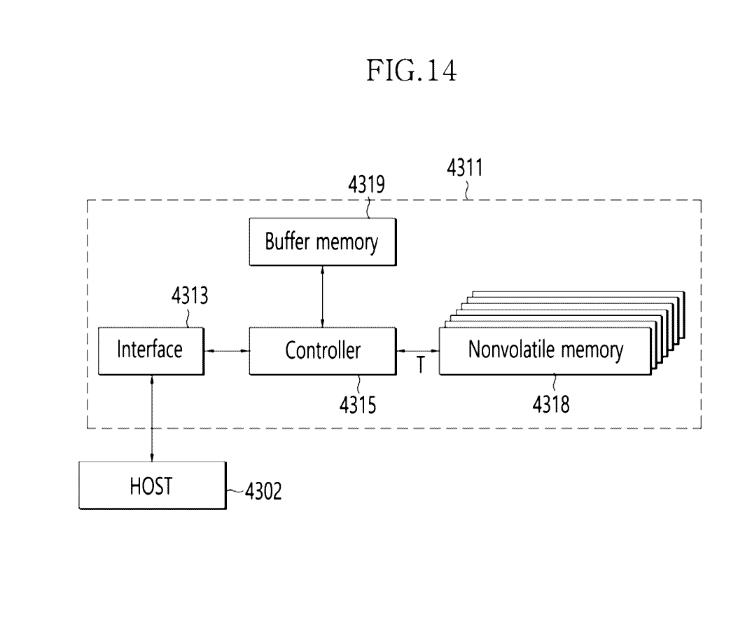

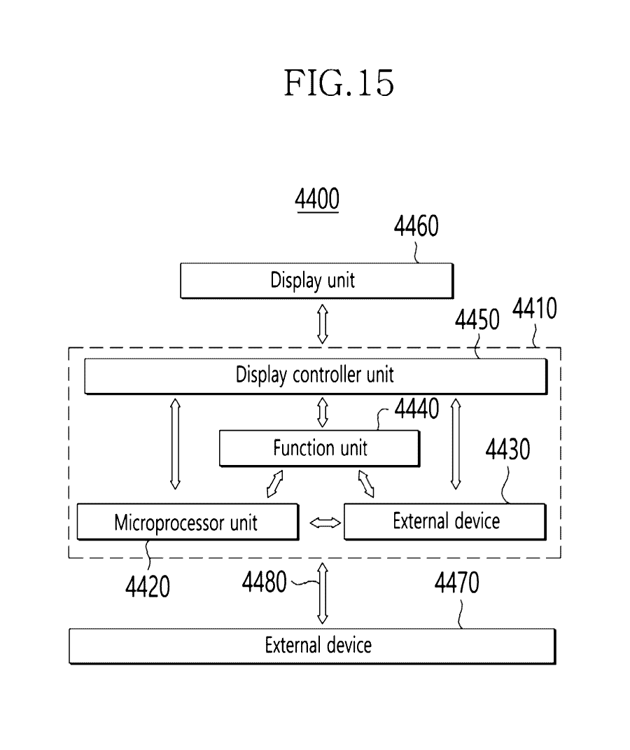

Descriptions will be made below for the detailed realization and modified examples of the electronic apparatus 4200, with reference to FIGS. 14 and 15.

FIG. 14 is a block diagram illustrating a data storage apparatus according to an embodiment of the inventive concept. Referring to FIG. 14, a data storage apparatus 4311 such as a solid state disk (SSD) may be provided. The SSD 4311 may include an interface 4313, a controller 4315, a nonvolatile memory 4318, and a buffer memory 4319.

The SSD 4311 is an apparatus which stores information using a semiconductor device. The SSD 4311 is faster and has a lower mechanical delay or failure rate. The SSD 4311 also generates less heat and noise than a hard disk drive (HDD). Further, the SSD 4311 may be smaller and lighter than the HDD. The SSD 4311 may be widely used in a laptop PC, a net book, a desktop PC, an MP3 player, or a portable storage device.

The controller 4315 may be formed adjacent to the interface 4313 and may be electrically coupled to the interface 4313. The controller 4315 may be a microprocessor including a memory controller and a buffer controller. The nonvolatile memory 4318 may be formed adjacent to the controller 4315 and may be electrically coupled to the controller 4315 via a connection terminal T. The data storage capacity of the SSD 4311 may correspond to the nonvolatile memory 4318. The buffer memory 4319 may be formed adjacent to the controller 4315 and may be electrically coupled to the controller 4315.

The interface 4313 may be electrically coupled to a host 4302. The interface 4313 may also function to transmit and receive electrical signals such as data to and from the host 4302. For example, the interface 4313 may be a device which uses the same standard as SATA, IDE, SCSI, and/or a combination thereof. The nonvolatile memory 4318 may be electrically coupled to the interface 4313 via the controller 4315.

The nonvolatile memory 4318 may function to store the data received through the interface 4313. The nonvolatile memory 4318 may include the semiconductor integrated circuit device according to any one of the above-described embodiments. The nonvolatile memory 4318 has a characteristic that the data stored is retained even when power supply to the SSD 4311 is interrupted.

The buffer memory 4319 may include a volatile memory. The volatile memory may be a DRAM and/or an SRAM. The buffer memory 4319 has a relatively higher operation speed than the nonvolatile memory 4318.

The data processing speed of the interface 4313 may be relatively faster than the operation speed of the nonvolatile memory 4318. The buffer memory 4319 may function to temporarily store data. The data received through the interface 4313 may be temporarily stored in the buffer memory 4319 via the controller 4315. Further, the data may then be permanently stored in the nonvolatile memory 4318 in conformity with the data recording speed of the nonvolatile memory 4318.

The data frequently used among the data stored in the nonvolatile memory 4318 may be read in advance and may be temporarily stored in the buffer memory 4319. Namely, the buffer memory 4319 may function to effectively increase an operation speed of the SSD 4311 and reduce an error occurrence rate.

FIG. 15 is a block diagram illustrating an electronic apparatus according to an embodiment of the inventive concept. Referring to FIG. 15, an electronic system 4400 including a body 4410, a microprocessor unit 4420, a power unit 4430, a function unit 4440, and a display controller unit 4450 may be provided.

The body 4410 may be a mother board formed of a printed circuit board (PCB). The microprocessor unit 4420, the power unit 4430, the function unit 4440, and the display controller unit 4450 may be mounted on the body 4410. A display unit 4460 may be disposed inside the body 4410 or outside the body 4410. For example, the display unit 4460 may be disposed on a surface of the body 4410. The display unit 4460 may also display an image processed by the display controller unit 4450.

The power unit 4430 may function to receive a voltage from an external battery or the like, convert the voltage into desired voltage levels, and supply the converted voltages to the microprocessor unit 4420, the function unit 4440, the display controller unit 4450, and so forth. The microprocessor unit 4420 may receive a voltage from the power unit 4430 and control the function unit 4440 and the display unit 4460. The function unit 4440 may perform various functions of the electronic system 4400. For example, when the electronic system 4400 is a portable phone, the function unit 4440 may include various components capable of performing portable phone functions, such as output of an image to the display unit 4460 or output of a voice to a speaker by dialing or communication with an external device 4470. When a camera is mounted together, the function unit 4440 may serve as a camera image processor.

When the electronic system 4400 is electrically coupled to a memory card or the like to increase capacity, the function unit 4440 may be a memory card controller. The function unit 4440 may exchange signals with the external device 4470 through a wired or wireless communication unit 4480. When the electronic system 4400 requires a universal serial bus (USB) or the like to expand functions, the function unit 4440 may serve as an interface controller. Any one semiconductor integrated circuit device among the semiconductor integrated circuit devices according to the above-described embodiments may be applied to the microprocessor unit 4420, the function unit 4440, or both.

The above embodiment of the invention is illustrative and not limitative. Various alternatives and equivalents are possible. The invention is not limited by the embodiment described herein. Nor is the invention limited to any specific type of semiconductor device. Other additions, subtractions, or modifications are obvious in view of the invention and are intended to fall within the scope of the appended claims.

What is claimed is:

1. A variable resistive memory device comprising:
a phase change region having a sidewall and a bottom surface;
a linear phase change layer formed along the sidewall and the bottom surface of the phase change region;
a gap-filling layer formed in the phase change region and surrounded by the phase change layer; and
an upper electrode formed over the phase change layer and the gap-filling layer.

2. The variable resistive memory device of claim 1,
wherein one end of the phase change layer is positioned at a sidewall portion below a top of the phase change region.

3. The variable resistive memory device of claim 2,
wherein an upper surface of the gap-filling layer is located at a lower level than an upper surface of the phase change layer.

4. The variable resistive memory device of claim 3,
wherein the upper surface of the phase change layer is located at a first level,
wherein an upper surface of the upper electrode is located at a second level, and
wherein the second level is as same as or higher than the first level.

5. A variable resistive memory device comprising:
a semiconductor substrate including an access device;
a lower electrode coupled to the access device;
an insulating interlayer formed over the lower electrode;
a phase change contact hole formed in the insulating interlayer and exposing the lower electrode;
a phase change layer formed over a sidewall and a bottom surface of the phase change contact hole;
a gap-filling layer formed in a lower region of the phase change contact hole and over the phase change layer; and
an upper electrode formed in an upper region of the phase change layer and over the gap-filling layer.

6. The variable resistive memory device of claim 5,
wherein the access device comprises a channel substantially perpendicular to an upper surface of the semiconductor substrate.

7. The variable resistive memory device of claim 5,
wherein one end of the phase change layer is positioned at a sidewall portion below a top of the phase change region, and the phase change layer is configured in a U-shape.

8. The variable resistive memory device of claim 7,
wherein an upper surface of the gap-filling layer is located at a lower level than an upper surface of the phase change layer.

9. The variable resistive memory device of claim 7,
wherein the upper surface of the phase change layer is located at a first level,
wherein an upper surface of the upper electrode is located at a second level, and
wherein the second level is as same as or higher than the first level.

10. A method of manufacturing a variable resistive memory device, the method comprising:
forming an insulating interlayer over a semiconductor substrate;
patterning the insulating interlayer to form a phase change contact hole;
forming a preliminary phase change layer over an inner surface of the phase change contact hole, wherein the preliminary phase change layer is a liner pattern;
forming a preliminary gap-filling layer over the phase change layer to fill the phase change contact hole;
patterning the preliminary gap-filling layer to form a gap-filling layer, wherein the gap-filling layer is formed in a lower portion of the phase change contact hole;
patterning the preliminary phase change layer to form a phase change layer, wherein the phase change layer is formed between the gap-filling layer and the insulating interlayer; and
forming an upper electrode in an upper portion of the phase change contact hole and over the gap-filling layer.

11. The method of claim 10,
wherein the preliminary phase change layer is formed by an atomic layer deposition (ALD) process.

12. The method of claim 10,
wherein the patterning of the preliminary phase change layer includes etching the preliminary change layer anisotropically to expose the upper portion of the phase change contact hole.

13. The method of claim 12,
wherein an upper surface of the gap-filling layer is located at a lower level than an upper surface of the phase change layer.

14. The method of claim 10,
wherein the semiconductor substrate comprises an access device and a lower electrode under the access device, and
wherein the phase change contact hole exposes the lower electrode.

15. The method of claim 14, wherein forming the access device comprises:
forming a vertical pillar over the semiconductor substrate;
forming a source in a lower portion of the vertical pillar;
forming a drain in an upper portion of the vertical pillar; and
forming a gate between the source and the drain,
wherein the gate surrounds the vertical pillar.
